(19) United States
(12) Patent Application Publication
(10) Pub. No.: US 2003/0184892 A1
(43) Pub. Date: Oct. 2, 2003

(54) Multi-layer mirror for a luminescent device and method for forming the same

(75) Inventors: Tung-Kuei Lu, Hualien (TW); Wei-Hsiang Wang, Taipei (TW)

Correspondence Address: QUINTERO LAW OFFICE, 1617 BROADWAY, 3RD FLOOR, SANTA MONICA, CA, 90404, US

(73) Assignee: Ritek Corporation

(21) Appl. No.: 10/385,026

(22) Filed: Mar. 10, 2003

(30) Foreign Application Priority Data
Mar. 29, 2002 (TW) 91106448

(51) Int. Cl. G02B 5/08

(52) U.S. Cl. 359/883; 359/900

(57) ABSTRACT

A multi-layer mirror for a micro-cavity structure of a luminescent device and method for forming the same. A buffer layer is formed on a transparent substrate of a luminescent device. A plurality of thin films of different refractive indices is formed on the buffer layer to serve as a multi-layer mirror.

### BACKGROUND OF THE INVENTION

1. Field of the Invention

The invention relates to a multi-layer mirror for a micro-cavity structure of a luminescent device and a method of forming the same. More particularly, the present invention relates to a organic light emitting diode (OLED) with a buffer layer for increasing adhesion between a multi-layer mirror and a substrate so as to stabilize processes and prevent cracking or peeling from poor adhesion.

2. Description of the Related Art

Organic light emitting diode (OLED) is classified according to the material of the organic luminescent film. One type is a molecule-based device system that uses chromogenic organic compound to form the organic luminescent film, and the other type is a polymer-based device system that uses conjugated polymer to form the organic luminescent film. Since the OLED has the same characteristics as light emitting diode (LED), the molecule-based device is called small-molecule OLED (SMOLED), and the polymer-based device is called polymer OLED.

Basically, the operation of the OLED is similar to a conventional semiconductor LED. When an outer voltage is applied to the OLED, both the electrons generated from a cathode layer and the holes generated from an anode layer move to reach an organic luminescent film, and then bombard the film and combine to transform electricity into luminosity. The luminescent color mainly depends on fluorescent nature of the organic luminescent film, in which a small amount of guest luminescent material is mixed with host luminescent material to promote luminescent efficiency, resulting in luminescent colors across the whole visible-light spectrum.

Light is one form of wave energy. For human beings, an optic nerve is receptive to red light, green light and blue light, and the three colors may mix to perform other colors. In other words, the exterior signals of red light, green light and blue light are combined by cones in the retina to result in other light colors not actually existent. For visible light, the wavelength of red light is about 6000 Å, the wavelength of green light is about 5500 Å, and the wavelength of blue light is about 4650 Å. In comparison, red light has a larger wavelength and smaller scatter, and blue light has the smaller wavelength, causing more scatter. According to the different wavelength natures, the OLED encounters insufficient luminescent efficiency.

In order to solve problems of anisotropic light emitting in the luminescent device, various structures of luminescent devices have been developed. For example, a micro-cavity structure has been developed to introduce and enhance light-wave resonance of a predetermined wavelength toward the surface of the luminescent device. Also, in the micro-cavity structure, a multi-layer mirror provides a substrate and a conductive layer to achieve phase shift, thus a light-wave resonance of a predetermined color is enhanced.

During the process of production, however, many technical problems are not found in the laboratory. For example, the adhesion between the substrate and the coating layer of the multi-layer mirror is poor, such that the multi-layer mirror easily cracks or peels from the substrate during subsequent deposition steps.

### SUMMARY OF THE INVENTION

Accordingly, an object of the invention is to provide a multi-layer mirror for a micro-cavity structure of a luminescent device and a method of forming the same, in which a buffer layer, such as a polymer of high transparency or an inorganic film of high transparency, is provided to increase adhesion between the multi-layer mirror and a substrate so as to stabilize processes and prevent cracking and peeling.

To achieve these and other advantages, the invention provides a multi-layer mirror for a micro-cavity structure of a luminescent device and a method of forming the same. A buffer layer is formed on a transparent substrate of a luminescent device. A plurality of thin films of different refractive indices is sputtered on the buffer layer to serve as a multi-layer mirror.

### DESCRIPTION OF THE DRAWINGS

For a better understanding of the present invention, reference is made to a detailed description to be read in conjunction with the accompanying drawings, in which:

FIG. 1 is a sectional diagram of a conventional OLED; and

FIG. 2 is a sectional diagram of a multi-layer mirror for a micro-cavity structure of a luminescent device according to the present invention.

### DETAILED DESCRIPTION OF THE INVENTION

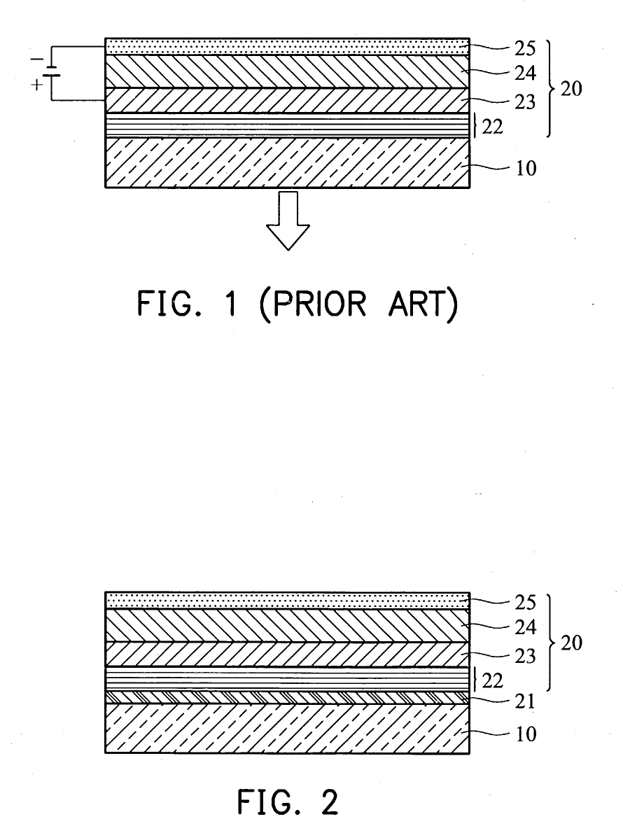

FIG. 1 is a sectional diagram of a conventional OLED. The conventional OLED comprises a transparent substrate 10 and a micro-cavity structure 20 constituting successive depositions of a multi-layer mirror 22, a transparent electrode layer 23, a luminescent material layer 24 and a top electrode layer 25 on the transparent substrate 10.

When a bias voltage is applied between the transparent electrode layer 23 and the top electrode layer 25, both the electrons generated from a cathode and the holes generated from an anode move to reach the luminescent material layer 24, and then bombard the luminescent material layer 24 and combine to transform electricity into luminosity. The luminescent color mainly depends on the fluorescent nature of the organic luminescent film, in which a small amount of guest luminescent material is mixed with host luminescent material to promote luminescent efficiency, resulting in luminescent colors across the whole visible-light spectrum.

Between the transparent substrate 10 and the transparent electrode layer 23, the multi-layer mirror 22 comprises many layers of thin film of different refractive indices which are directly deposited on the transparent substrate 10 by chemical evaporation. In accordance with the thickness and refractive index (n) of the thin film, a phase shift is generated to reduplicate resonance when light of a predetermined wavelength passes through the thin film. Thus, the intensity of red, green, or blue light from the OLED is enhanced.

Theoretically, as the layers of thin film in the multi-layer mirror 22 increase, enhancement of the light intensity is increased commensurately. In mass production, however, as the layers of thin film in the multi-layer mirror 22 increase, process difficulties intensify and the likelihood of peeling from the transparent substrate 10 is increased. Moreover, chemical evaporation has disadvantages of slow production, expensive facilities, and difficulties in broadening mass production. If a sputtering method is substituted for chemical evaporation when depositing the multi-layer mirror 22, the facility cost is decreased and the production rate is increased.

A preferred embodiment of the present invention is now described with reference to FIG. 2. In comparison with the conventional OLED shown in FIG. 1, the present invention further provides a buffer layer 21 between the transparent substrate 10 and the multi-layer mirror 22 of the micro-cavity structure 20. Hereinafter, a method of forming the multi-layer mirror 22 of the micro-cavity structure 20 according to the present invention is described.

First, using coating or sputtering, at least one buffer layer 21 is deposited on the transparent substrate 10. The buffer layer 21 is a polymer of high transparency or an inorganic film of high transparency. Then, using sputtering, many layers of thin film of different refractive indices are deposited on the buffer layer 21 to serve as the multi-layer mirror 22.

Next, a transparent electrode layer 23, a luminescent material layer 24 and a metal reflective layer 25 are successively deposited on the multi-layer mirror 22 to complete a main structure of a luminescent device, such as an OLED. The material and process related to the multi-layer mirror 22 have been disclosed in U.S. Pat. No. 5,405,710, U.S. Pat. No. 5,814,416 and U.S. Pat. No. 6,278,236, but do not disclose the aims and key points of the present invention.

The transparent substrate 10 is glass or transparent plastic. Preferably, the transparent substrate 10 is polycarbonate, and the buffer layer 21 is deposited thereon by spin coating or sputtering. The buffer layer 21 is a polymer of high transparency or an inorganic film of high transparency. Specifically, SD-101 type or SD-715 type lacquer produced by DIC Company of Japan has been tested to prove the effects of the buffer layer 21 described in the present invention.

The multi-layer mirror 22 is formed by repeatedly evaporating or sputtering thin films of different refractive indices on the buffer layer 21. Preferably, the odd-layered thin film (A) is SiₓN_{y}, and the even-layered thin film (B) is SiO₂. Alternatively, the odd-layered thin film (A) can be SiO₂, and the even-layered thin film (B) SiₓN_{y}. (wherein x, y=N, N is Nature Number) The thickness of each material thin film is about λ/4n, wherein λ indicates the light wavelength, and n indicate the refractive index of the thin film.

The film (A) or (B) mentioned above could be replaced by other material, for example, the mixture ZnS—SiO₂ or alloy AlTiN (index of ZnS—SiO₂/AlTiN=2.3/2.0 at 116 nm thickness of λ/4 wavelength).

In experimental results, the buffer layer 21 between the transparent substrate 10 and the multi-layer mirror 22 increases adhesion and stabilizes processes. In a contrasting experiment using a first sample without a buffer layer and a second sample with the buffer layer, a tape of 40 oz/inch² adhesion is applied to a multi-layer mirror 22 of the first sample and the second sample respectively, and then the tape is torn so as to perform an adhesion test. The results are listed below.

| Layers of | | Multi-layer | |
|---|---|---|---|
| thin film in | | mirror | Multi-layer |
| a multi-layer | Mirror | without a | mirror with a |
| mirror | structure | buffer layer | buffer layer |
| 1 layer | A | 100% pass | 100% pass |
| 2 layers | A/B | 100% pass | 100% pass |
| 3 layers | A/B/A | 100% pass | 100% pass |
| 4 layers | A/B/A/B | 50% pass | 100% pass |
| 5 layers | A/B/A/B/A | 50% pass | 100% pass |
| 6 layers | A/B/A/B/A/B | 50% pass | 100% pass |
| 7 layers | A/B/A/B/A/B/A | 50% pass | 100% pass |

“A” indicates a SiₓN_{y} film, “B” indicates a SiO₂ film, the thickness of each about λ/4n, wherein λ indicates the light wavelength, and n the refractive index of the thin film.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of forming a multi-layer mirror for a micro-cavity structure of a luminescent device, comprising the steps of:
forming a buffer layer on a transparent substrate of a luminescent device; and
sputtering a plurality of thin films of different refractive indices on the buffer layer to serve as a multi-layer mirror.

2. The method of forming a multi-layer mirror for a micro-cavity structure of a luminescent device as claimed in claim 1, wherein the buffer layer is formed on the transparent substrate by coating or sputtering, and increases adhesion between the multi-layer mirror and the transparent substrate.

3. The method of forming a multi-layer mirror for a micro-cavity structure of a luminescent device as claimed in claim 1, wherein the buffer layer is a polymer of high transparency, increasing adhesion between the multi-layer mirror and the transparent substrate.

4. The method of forming a multi-layer mirror for a micro-cavity structure of a luminescent device as claimed in claim 1, wherein the buffer layer is an inorganic film of high transparency, increasing adhesion between the multi-layer mirror and the transparent substrate.

5. The method of forming a multi-layer mirror for a micro-cavity structure of a luminescent device as claimed in claim 1, wherein the step of forming the multi-layer mirror comprises a step of sputtering a SiO₂ layer on the buffer layer.

6. The method of forming a multi-layer mirror for a micro-cavity structure of a luminescent device as claimed in claim 1, wherein the step of forming the multi-layer mirror comprises a step of sputtering a SiₓN_{y} layer on the buffer layer.

7. The method of forming a multi-layer mirror for a micro-cavity structure of a luminescent device as claimed in claim 1, wherein the step of forming the multi-layer mirror comprises a step of sputtering a ZnS—SiO₂ mixture on the buffer layer.

8. The method of forming a multi-layer mirror for a micro-cavity structure of a luminescent device as claimed in claim 1, wherein the step of forming the multi-layer mirror comprises a step of sputtering an AlTiN alloy on the buffer layer.

9. The multi-layer mirror for a micro-cavity structure of a luminescent device as claimed in claim 1, wherein the luminescent device is organic light emitting diode (OLED).

10. A multi-layer mirror for a micro-cavity structure of a luminescent device, comprising: a transparent substrate;
a buffer layer on the transparent substrate; and
a multi-layer mirror on the buffer layer;
wherein the buffer layer increases adhesion between the transparent substrate and the multi-layer mirror.

11. The multi-layer mirror for a micro-cavity structure of a luminescent device as claimed in claim 10, wherein the buffer layer is a polymer of high transparency.

12. The multi-layer mirror for a micro-cavity structure of a luminescent device as claimed in claim 10, wherein the buffer layer is an inorganic film of high transparency.

13. The multi-layer mirror for a micro-cavity structure of a luminescent device as claimed in claim 10, wherein the multi-layer mirror comprises at least two thin films of different refractive indices.

14. The multi-layer mirror for a micro-cavity structure of a luminescent device as claimed in claim 10, wherein the multi-layer mirror comprises a SiO₂ layer.

15. The multi-layer mirror for a micro-cavity structure of a luminescent device as claimed in claim 10, wherein the multi-layer mirror comprises a SiₓN_{y} layer.

16. The multi-layer mirror for a micro-cavity structure of a luminescent device as claimed in claim 10, wherein the multi-layer mirror comprises a ZnS—SiO₂ mixture.

17. The multi-layer mirror for a micro-cavity structure of a luminescent device as claimed in claim 10, wherein the multi-layer mirror comprises an AlTiN alloy.

18. The multi-layer mirror for a micro-cavity structure of a luminescent device as claimed in claim 10, wherein the transparent substrate is glass.

19. The multi-layer mirror for a micro-cavity structure of a luminescent device as claimed in claim 10, wherein the transparent substrate is polycarbonate.

20. The multi-layer mirror for a micro-cavity structure of a luminescent device as claimed in claim 10, wherein the luminescent device is organic light emitting diode (OLED).
